(19) United States
(12) Patent Application Publication
(10) Pub. No.: US 2012/0001328 A1
(43) Pub. Date: Jan. 5, 2012

(54) CHIP-SIZED PACKAGE AND FABRICATION METHOD THEREOF

(75) Inventors: Chiang-Cheng Chang, Taichung (TW); Chien-Ping Huang, Taichung (TW); Chun-Chi Ke, Taichung Hsien (TW)

(73) Assignee: SILICONWARE PRECISION INDUSTRIES CO., LTD., Taichung (TW)

(21) Appl. No.: 12/967,844

(22) Filed: Dec. 14, 2010

(30) Foreign Application Priority Data
Jun. 30, 2010 (TW) 099121402

(51) Int. Cl. H01L 23/498; H01L 21/78

(52) U.S. Cl. 257/738; 438/113; 257/E23.069; 257/E21.599

(57) ABSTRACT

A chip-sized package and a fabrication method thereof are provided. The method includes forming a protection layer on an active surface of a chip and attaching a non-active surface of the chip to a carrier made of a hard material; performing a molding process and removing a protection layer from the chip; performing an RDL process to prevent problems as encountered in the prior art, such as softening of adhesive films, an encapsulant overflow, a pliable chip and chip deviation or contamination caused by directly adhering the active surface of the chip to the adhesive film that may even lead to inferior electrical contacts between a circuit layer and a plurality of chip bond pads during subsequent RDL process, and cause the package to be scraped. Further, the carrier employed in this invention can be repetitively used in the process to help reduce manufacturing costs.

### BACKGROUND OF THE INVENTION

1. Field of the Invention

The present invention relates to semiconductor packages and fabrication methods thereof, and more particularly, to a chip-sized package and a fabrication method thereof.

2. Description of Related Art

Along with the advancement of the semiconductor technology, semiconductor products have been developed in a variety of different package types. In the pursuing of a lighter, thinner and smaller semiconductor package structure, a chip scale package (CSP) structure has been developed. The feature of this chip scale package structure is that its size is equal to or a little bit bigger than the chip size.

U.S. Pat. Nos. 5,892,179, 6,103,552, 6,287,893, 6,350,668, and 6,433,427 disclose a conventional CSP structure, which applies build-up layers directly on the top of the chip without using a chip carrier such as a substrate or a lead frame, and by means of the redistribution layer (RDL) technology to redistribute the bond pads of the chip to the intended positions.

However, the disadvantage of the aforementioned CSP structure is that the application of the redistribution technology or the distribution of the conductive traces on the chip is always restricted by the size of the chip or its active surface area, especially in the situation that the chip integration level is getting higher and the chip size is getting smaller, the chip can not even provide enough or more surface for installing higher number of solder balls for effectively electrically connecting to external devices.

In view of the aforementioned drawback, U.S. Pat. No. 6,271,469 discloses a fabrication method of a wafer level CSP (WLCSP) that forms a package with build-up layers on the chip, which provides more surface area to carry more input/output ends or solder balls.

As shown in FIG. 1A, an adhesive film 11 such as a thermal induction adhesive film is prepared, and a plurality of chips 12 are adhered to the adhesive film 11 via the active surfaces 121 thereof. As shown in FIG. 1B, a molding process is performed, an non-active surface 122 and a lateral of the chip 12 are encapsulated by an encapsulant 13 such as an epoxy resin, and then the adhesive film 11 is removed by heating to expose the active surface 121 of the chip 12. As shown in FIG. 1C, a dielectric layer 14 is formed on the active surface 121 of the chip 12 and the encapsulant 13 by the RDL technique, and a plurality of openings that penetrate the dielectric layer 14 are formed to expose bond pads 120 on the chip 12. Then a circuit layer 15 is formed on the dielectric layer 14, allowing the circuit layer 15 to be electrically connected to the bond pads 120. Furthermore, a solder mask 16 is formed on the circuit layer 15, and a plurality of solder balls 17 are implanted on predetermined positions of the circuit layer 15. Lastly, a singulation process is performed.

By the aforementioned fabrication method, the encapsulant that encapsulates the chip provides a surface area larger than the active surface of the chip and can provide installation of more solder balls to effectively electrically connect to external devices.

However, the drawbacks of the above processes include that, since the chip is adhered to the adhesive film with the active surface facing the adhesive film, the adhesive film is likely to extend or contract due to the heating to the adhesive film, and, as such, the chip is offset, and that the softened adhesive film resulting from the heat generated during the molding process makes the chip offset, such that the circuit layer cannot be connected to the bond pads of the chip during the subsequent RDL process, which results in poor electrical connection quality. Further, the adhesive film used in the fabrication method is an expendable material, thereby increasing manufacturing cost.

In addition, referring to FIG. 2, when in molding, the encapsulant 13 easily creates encapsulant overflow on the active surface 121 of the chip 12 or even contamination of the bond pads 120 that leads to inferior electrical contacts between a circuit layer and a plurality of chip bond pads during subsequent RDL process, and causes the package to be scraped.

Furthermore, referring to FIG. 3A, in the molding process, the plurality of the chips are carried only by the adhesive film 11 such that critical warpage problem tends to occur in the adhesive film 11 and the encapsulant 13. The warpage problem becomes more critical when the encapsulant 13 is made too thin, which leads to uneven thickness issue when in coating the dielectric layer on the chip during the subsequent RDL process. Accordingly, it is needed to provide an additional carrier 18 made of a hard material (as shown in FIG. 3B), for adhering the encapsulant 13 to the carrier 18 via an adhesive for the sake of flatting. Therefore, it increases production complexity and production costs. Meanwhile, after the RDL process is completed and the carrier is removed, the adhesive applied on the carrier still remains (as shown in FIG. 3C). Related structures and technologies are disclosed in U.S. Pat. Nos. 6,498,387, 6,586,822, 7,019,406, and 7,238,602.

Hence, it is critical issue in the industry as to how to provide a chip-sized package and its fabrication method which is capable of ensuring the quality of electrical connection between the circuit layer and the bond pads, enhancing the reliability of the finished products, and meanwhile decreasing the production cost.

### SUMMARY OF THE INVENTION

In view of the aforementioned drawbacks of the prior art, the present invention provides a fabrication method of a chip-sized package, comprising: providing a plurality of chips and a carrier, each of the chips having an active surface and a non-active surface opposing the active surface, each of the active surfaces having a plurality of bond pads formed thereon, each of the active surfaces having a protection layer formed thereon and the carrier having a first encapsulant formed thereon, wherein the non-active surfaces of the chips are attached to the first encapsulant; forming a second encapsulant for encapsulating the chips and exposing the protection layer on each of the active surfaces of the chips; removing the protection layer to expose the active surfaces of the chips; forming a dielectric layer on each of the active surfaces of the chips and the second encapsulant, the dielectric layer having a plurality of openings for exposing the bond pads; forming a circuit layer on the dielectric layer and electrically connecting the circuit layer to the bond pads; and forming a solder mask on the dielectric layer and the circuit layer, the solder mask having a plurality of openings for solder balls to be implanted therein, Subsequently, the fabrication method further comprises removing the carrier, and singulating the package to form a plurality of wafer level chip-sized packages.

The first encapsulant can be removed to make the package thinner in thickness and enhance heat dissipation efficiency. In addition, a circuit build-up structure is formed on the circuit layer by an RDL technique. In the fabrication method of the chip-sized package of the present invention, the adhesion between the second encapsulant and the first encapsulant is larger than the adhesion between the first encapsulant and the carrier, such that the carrier can be easily removed. Thus the fabricating process efficiency is accelerated, and the carrier can be repetitively used in the process to help reduce manufacturing costs.

By the aforementioned fabrication method, the present invention further discloses a chip-sized package, comprising: a chip having an active surface and a non-active surface opposing the active surface, a plurality of bond pads formed on the active surface; a second encapsulant encapsulating a periphery of the chip and being higher than the chip; a dielectric layer formed on the active surface and the second encapsulant, and having a plurality of openings for exposing the bond pads; and a circuit layer formed on the dielectric layer and electrically connected to the bond pads.

The package further comprises a solder mask formed on the dielectric layer and the circuit layer, and having a plurality of openings for exposing a part of the circuit layer, and a plurality of solder balls implanted on the exposed part of the circuit layer.

In addition, the package further comprises a first encapsulant formed on the non-active surface and the second encapsulant.

Therefore, the chip-sized package and the fabrication method thereof of the present invention are characterized by forming a protection layer on an active surface of the chip and attaching the non-active surface of the chip to a carrier made of a hard material; performing a molding process and removing the protection layer from the chip; performing an RDL process to prevent problems as encountered in prior arts, such as softening of adhesive films, an encapsulant overflow, a pliable chip and chip deviation or contamination caused by directly adhering the active surface of the chip to an adhesive film that may even lead to inferior electrical contacts between a circuit layer and a plurality of chip bond pads during the subsequent RDL process, and cause the package to be scraped. Further, in the present invention, the adhesion between the second encapsulant and the first encapsulant is larger than the adhesion between the first encapsulant and the carrier, such that the carrier can be easily removed. Accordingly, the efficiency of the fabricating process is accelerated, and the carrier can be repetitively used in the process to help reduce manufacturing costs. The present invention does not require the use of the adhesive film such that warpage problem caused by the adhesive film as encountered in the prior art can be prevented from occurrence, and problems such as fabrication complexity, increased production costs and the flash on encapsulant caused by the use of an additional carrier for solving the warpage problem.

### DESCRIPTION OF THE DRAWINGS

FIG. 1A to FIG. 1C show a fabrication method of a wafer level chip scale package (WLCSP) disclosed by U.S. Pat. No. 6,271,469;

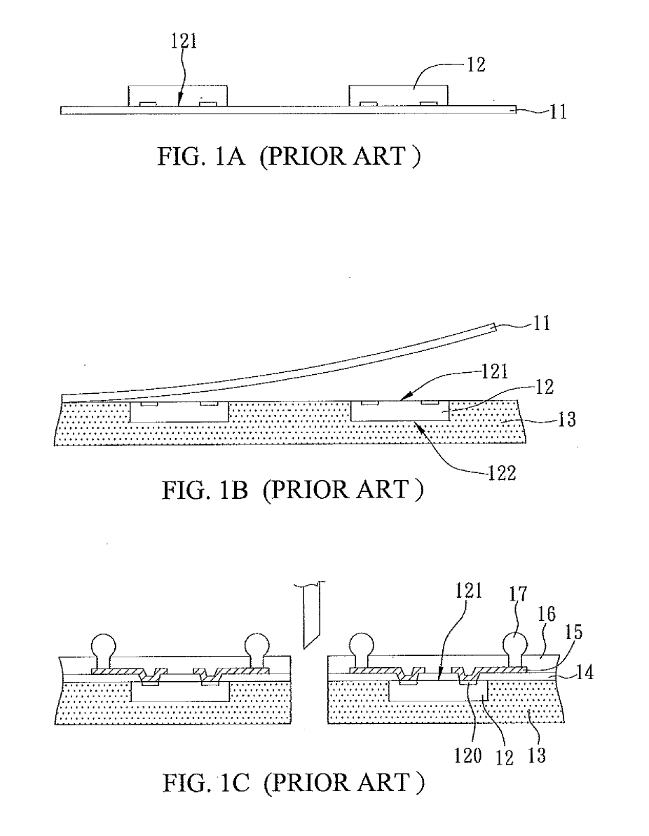

FIG. 2 shows an encapsulant overflow problem presented in WLCSP disclosed by U.S. Pat. No. 6,271,469;

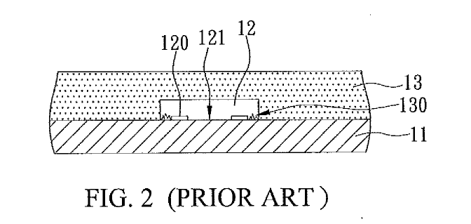

FIG. 3A to FIG. 3C show problems such as encapsulant warpage, adding a carrier, flash on the encapsulant surface presented in WLCSP disclosed by U.S. Pat. No. 6,271,469;

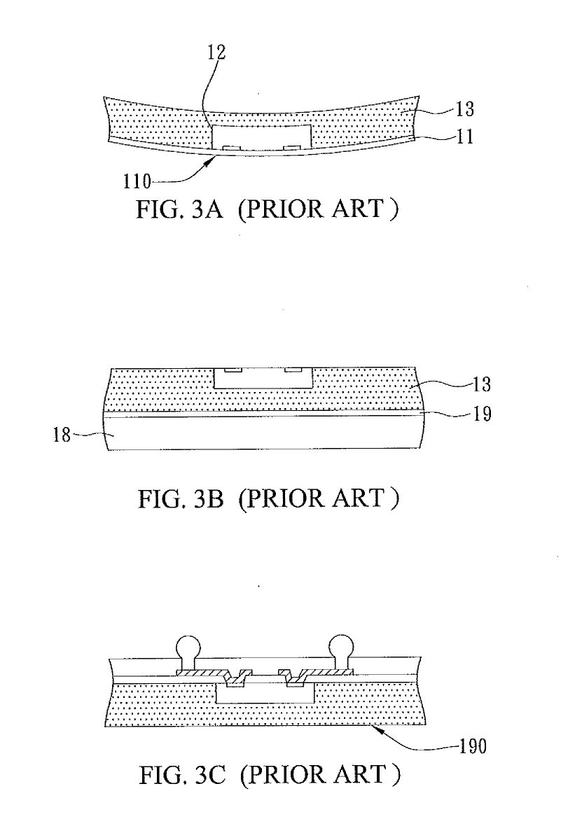

FIG. 4A to FIG. 4H showing a chip-sized package and a fabrication method thereof according to a first embodiment of the present invention;

FIG. 5 shows a chip-sized package and a fabrication method thereof according to a second embodiment of the present invention;

FIG. 6 shows a chip-sized package and a fabrication method thereof according to a third embodiment of the present invention; and

FIGS. 7A to FIG. 7D show a chip-sized package and a fabrication method thereof according to a fourth embodiment of the present invention.

### DETAILED DESCRIPTION OF PREFERRED EMBODIMENTS

The following illustrative embodiments are provided to illustrate the disclosure of the present invention, these and other advantages and effects can be apparently understood by those in the art after reading the disclosure of this specification.

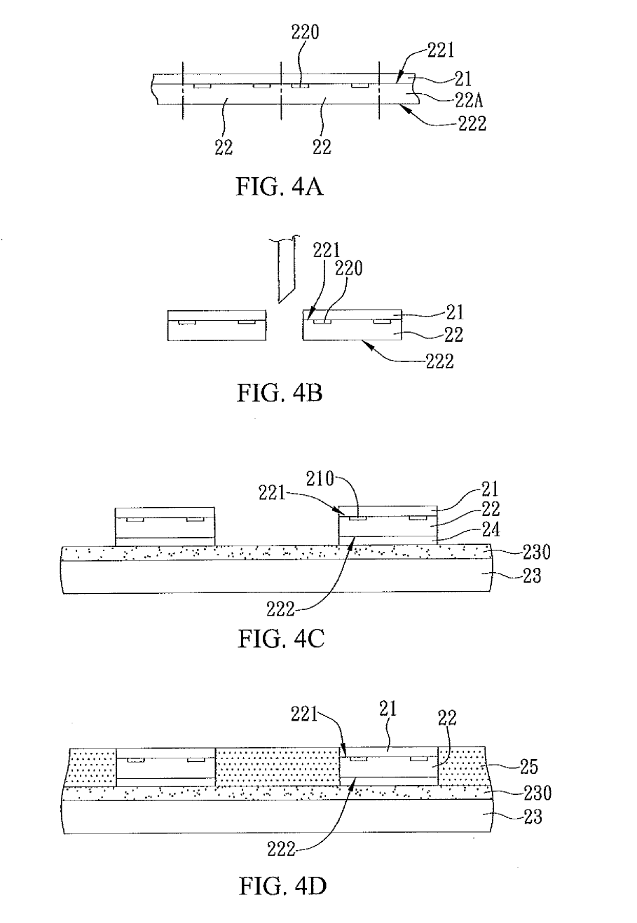

Referring to FIG. 4A to FIG. 4H, cross-sectional views showing a chip sized package and a fabrication method thereof according to a first embodiment of the present invention are illustrated.

As shown in FIG. 4A and FIG. 4B, a wafer 22A is provided with a plurality of chips 22 is provided, and the wafer 22A and the chips 22 each have an active surface 221 and a non-active surface 222 opposing the active surface 221, and a plurality of bond pads 220 are formed on the active surface 221 of each of the chips 22. A protection layer 21 is deposited on the active surface 221 of the wafer 22A. A thickness of the protection layer 21 is about 3 μm to 20 μm. Then the wafer 22 is singulated to form a plurality of chips 22, with the protection layer 21 formed on the active surface 221.

As shown in FIG. 4C, a carrier 23 made of a hard material is provided, and an first encapsulant 230 is formed on the carrier 23 for adhering the non-active surfaces 222 of the chips 22 to the first encapsulant 230 via a adhesive 24. A curing process is then performed to severely attach the chips to the first encapsulant 230. The first encapsulant 230 is made of ink comprising epoxy resin.

As shown in FIG. 4D, a second encapsulant 25 made of an epoxy resin material is formed to encapsulate the chips 22 by means of a molding technique, leaving the protective layer 21 on the active surfaces 221 of the chips 22 to be exposed. The adhesion between the second encapsulant 25 and the first encapsulant 230 is larger than the adhesion between the first encapsulant 230 and the carrier 23. Accordingly, the carrier 23 may be easily removed in the subsequent process.

As shown in FIG. 4E, the protection layer 21 is removed by means of chemical agent to expose the active surfaces 221 of the chips 22. Accordingly, the top surface of the second encapsulant 25 can be higher than the active surface 221 of the chip 22.

As shown in FIG. 4F, a dielectric layer 26 is formed on the active surfaces 221 of the chips 22 and the second encapsulant 25, and a plurality of openings are formed in the dielectric layer 26 by a photo-lithography process or laser process to expose the bond pads 220. The dielectric layer 26 is a seed layer for a subsequent circuit layer to be formed thereon.

Furthermore, a circuit layer 27 is formed on the dielectric layer 26 by an RDL technique, and is electrically connected to the bond pads 220. As shown in FIG. 4G, a solder mask 28 is formed on the dielectric layer 26 and the circuit layer 27, and a plurality of openings are formed in the solder mask 28 to expose a part of the circuit layer 27 where solder balls 29 are to be implanted thereon.

As shown in FIG. 4H, the adhesion between the second encapsulant and the first encapsulant is larger than the adhesion between the first encapsulant and the carrier. As a result, the carrier 23 can be easily removed. And then a singulation process is performed to form a plurality of wafer level chip-sized packages.

By the aforementioned fabrication method, the present invention also discloses a chip-sized package having a chip 22 which has an active surface 221 and a non-active surface 222 opposing the active surface 221, and a plurality of bond pads 220 are formed on the active surface 221; a second encapsulant 25 which encapsulates a periphery of the chip 22 and is higher than the chip 22; a dielectric layer 26 which is formed on the active surface 221 of the chip 22 and the second encapsulant 25, and has a plurality of openings to expose the bond pads 220; a circuit layer 27 which is formed on the dielectric layer 27 and electrically connected to the bond pads 220; a solder mask 28 which is formed on the dielectric layer 26 and the circuit layer 27, and has a plurality of openings to expose a part of the circuit layer 27; and solder balls 29 which are implanted on the exposed part of the circuit layer 27. In addition, the package comprises a first encapsulant 230 formed on the non-active surface 222 of the chip 22 and the second encapsulant 25.

Therefore, the chip-sized package and the fabrication method thereof of the present invention is characterized by depositing a protection layer on an active surface of the chip and attaching the chip to a carrier made of a hard material via the non-active surface of the chip; performing a molding process and removing the protection layer from the chip; performing an RDL process to prevent the problems as encountered in the prior art, such as softening of adhesive films, an encapsulant overflow, a pliable chip and chip deviation or contamination caused by directly adhering the active surface of the chip to an adhesive film that may even lead to inferior electrical contacts between a circuit layer and a plurality of chip bond pads in the subsequent RDL process, and cause the package to be scraped. Further, in the present invention, the adhesion between the second encapsulant and the first encapsulant is larger than the adhesion between the first encapsulant and the carrier, so the carrier can be easily removed. As a result, the efficiency of the fabricating process is accelerated, and the carrier can be repetitively used in the process to help reduce the manufacturing costs. Meanwhile the present invention does not require the use of the adhesive film so that warpage problem caused by the adhesive film as encountered in the prior art can be prevented, and problems such as fabrication complexity, increased production costs and flash on the encapsulant caused by the us of an additional carrier for solving the warpage problem can also be eliminated.

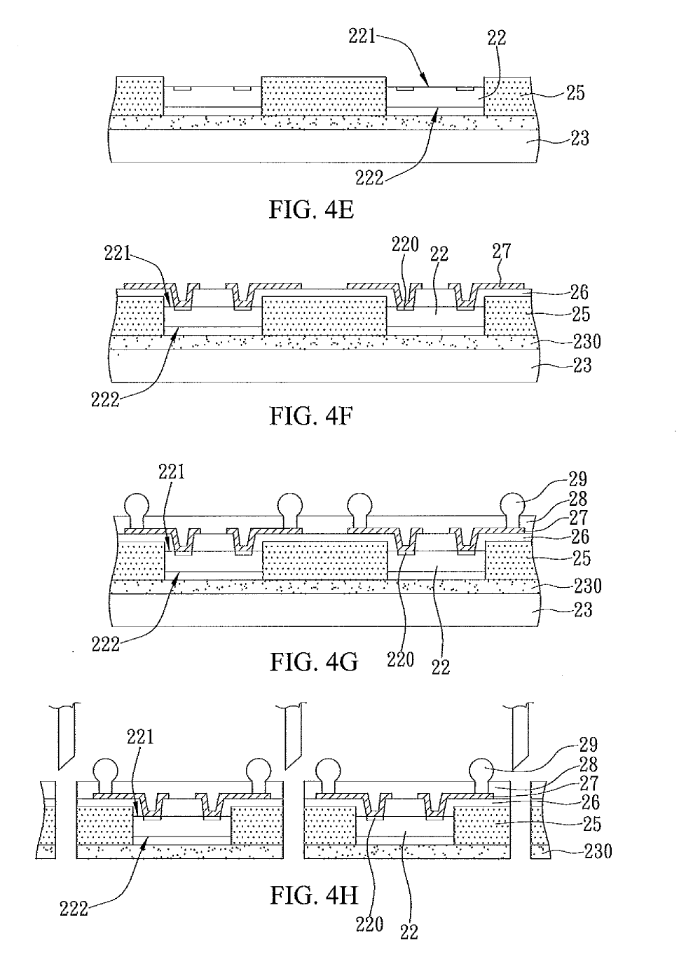

Referring to FIG. 5, it shows a chip sized package and a fabrication method thereof according to a second embodiment of the present invention. As shown in FIG, 5, the chip-sized package is substantially similar to the one disclosed in the aforementioned embodiment, except that the first encapsulant can be removed to make the package thinner, and to help dissipate heat produced from the chip during operation, to thereby improve the heat dissipation efficiency.

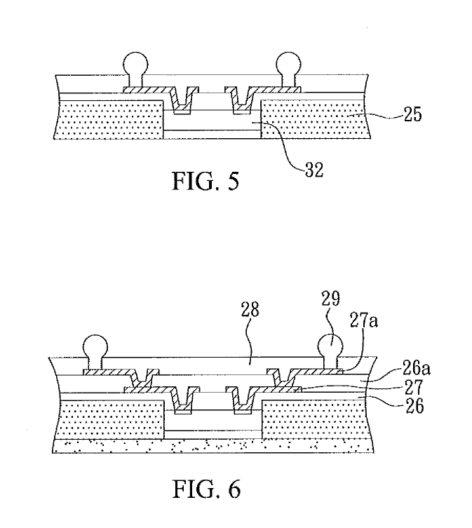

Further referring to FIG. 6, it shows a chip sized package and a fabrication method thereof according to a third embodiment of the present invention. As shown in FIG. 6, the chip-sized package is substantially similar to the one disclosed in the aforementioned embodiment, except that a build-up structure is formed on the dielectric layer and circuit layer. For example, a second dielectric layer 26a and a second circuit layer 27a are formed on the dielectric layer 26 and circuit layer 27 formed previously, and the second circuit layer 27a is electrically connected to the circuit layer 27. After that, the solder mask 28 is formed on the second circuit layer 27a, a plurality of openings penetrate the solder mask 28 are formed to expose a part of the second circuit layer 27a. Then, solder balls 29 are implanted on the exposed part of the circuit layer 27a. The solder balls 29 serve as the input/output ends of the package and thus may be electrically connected to external devices. Therefore, the flexibility of the circuit layout of the package can be enhanced by increasing the number of the build-up layer on the chip.

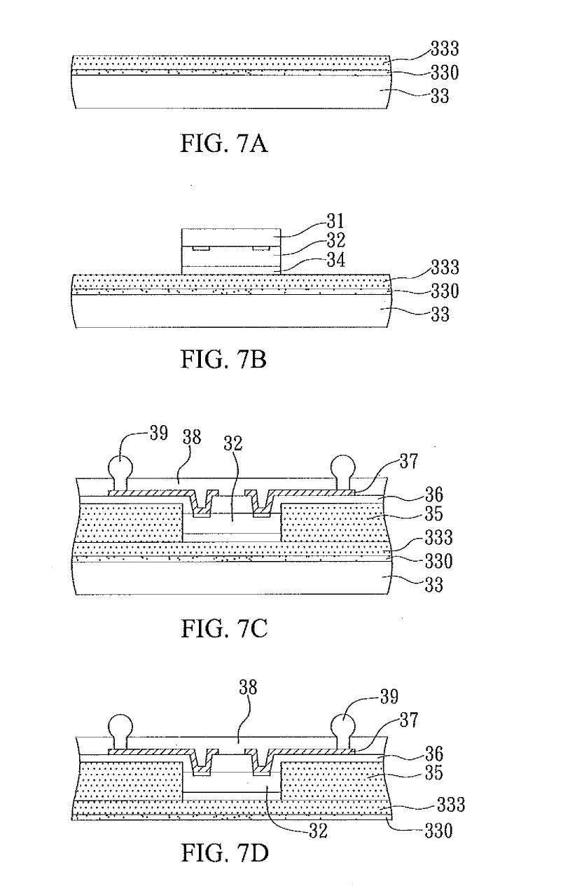

Referring to FIG. 7A to FIG. 7D, they show a chip sized package and a fabrication method thereof according to a fourth embodiment of the present invention. The present embodiment is substantially similar to the one disclosed in the aforementioned embodiment, except that an additional enhanced protection layer is formed on the non-active surface of the chip for protecting the chip.

As shown in FIG. 7A, a carrier 33 made of a hard material is provided, a first encapsulant 330 is coated on the carrier 33, and an enhanced protection layer 333 made of a material such as an epoxy molding compound (EMC) is formed on the first encapsulant 330 by means of a molding technique. The adhesion between the first encapsulant 330 and the enhanced protection layer 333 is larger than the adhesion between the first encapsulant 330 and the carrier 33.

As shown in FIG. 7B, a protection layer 31 is formed on an active surface of a chip 32, and a non-active surface of the chip 32 is adhered to the enhanced protection layer 333 by an adhesive 34.

As shown in FIG. 7C, a second encapsulant 35 made of a material such as an epoxy molding compound is formed to encapsulate the chip 32 by means of a molding technique, leaving the protection layer 31 on the active surface of the chip 32 to be exposed from the second encapsulant 35. Then, the protection layer 31 is removed to expose the active surface of the chip 32. Further, a dielectric layer 36 is formed on the active surface of the chip 32 and the second encapsulant 35, and a circuit layer 37 is formed on the dielectric layer 36.

After that, a solder mask 38 is formed on the dielectric layer 36 and the circuit layer 37, and solder balls 39 are implanted.

As shown in FIG. 7D, lastly, the carrier 33 can be removed and a singulation process can be performed.

Accordingly, the non-active surface of the chip 33 can be formed with an enhanced protection layer so as to provide a better protection.

The above-described descriptions of the detailed embodiments are only to illustrate the preferred implementation according to the present invention, and it is not to limit the scope of the present invention, accordingly, all modifications and variations completed by those with ordinary skill in the art should fall within the scope of present invention defined by the appended claims.

1. A fabrication method of a chip-sized package, comprising:
providing a plurality of chips and a carrier, each of the chips having an active surface and a non-active surface opposing the active surface, each of the active surfaces having a plurality of bond pads formed thereon, forming a each of the active surfaces having a protection layer formed thereon, and the carrier having a first encapsulant formed thereon, wherein the plurality of chips are attached to the first encapsulant via the non-active surface of each of the chips;
forming a second encapsulant for encapsulating the chips and exposing the protection layer on each of the active surfaces of the chips;
removing the protection layer to expose the active surfaces of the chips;
forming a dielectric layer on each of the active surfaces of the chips and the second encapsulant, the dielectric layer having a plurality of openings for exposing the bond pads from the openings; and
forming on the dielectric layer a circuit layer electrically connected to the bond pads.

2. The method as claimed in claim 1, further comprising forming a solder mask on the dielectric layer and the circuit layer, the solder mask having a plurality of openings for solder balls to be implanted therein.

3. The method as claimed in claim 2, further comprising removing the carrier, and singulating the package.

4. The method as claimed in claim 3, further comprising removing the first encapsulant.

5. The method as claimed in claim 1, wherein the adhesion between the second encapsulant and the first encapsulant is larger than the adhesion between the first encapsulant and the carrier.

6. The method as claimed in claim 1, wherein the second encapsulant is higher than the chip.

7. The method as claimed in claim 1, further comprising forming a circuit build-up structure on the circuit layer by an RDL technique.

8. The method as claimed in claim 1, wherein the chips are fabricated by: providing a wafer having the chips, the wafer having an active surface and a non-active surface opposing the active surface; forming the protection layer on the active surface of the wafer; and singulating the wafer to form the chips with the protection layer formed on the active surfaces of the chips.

9. The method as claimed in claim 1, further comprising forming an enhanced protection layer on the first encapsulant, for the chips to be mounted thereon.

10. The method as claimed in claim 9, wherein the enhanced protection layer is formed by a molding technique.

11. The method as claimed in claim 10, wherein the enhanced protection layer is formed by an epoxy molding compound.

12. The method as claimed in claim 9, wherein the adhesion between the enhanced protection layer and the first encapsulant is larger than the adhesion between the first encapsulant and the carrier.

13. The method as claimed in claim 1, wherein the second encapsulant is formed to encapsulate the chips by means of a molding technique.

14. The method as claimed in claim 1, wherein the first encapsulant is made of ink comprising epoxy resin.

15. A chip-sized package, comprising:
a chip having an active surface and a non-active surface opposing the active surface, with a plurality of bond pads formed on the active surface;
a second encapsulant encapsulating a periphery of the chip and being higher than the chip;
a dielectric layer formed on the active surface and the second encapsulant, and having a plurality of openings for exposing the bond pads; and
a circuit layer formed on the dielectric layer and electrically connected to the bond pads.

16. The package as claimed in claim 15, further comprising:
a solder mask formed on the dielectric layer and the circuit layer, and having a plurality of openings for exposing a part of the circuit layer; and
solder balls implanted on the exposed part of the circuit layer.

17. The package as claimed in claim 15, further comprising a first encapsulant encapsulating the non-active surface of the chip and the second encapsulant.

18. The package as claimed in claim 15, further comprising an enhanced protection layer formed on the non-active surface of the chip and the second encapsulant.

19. The package as claimed in claim 18, wherein the enhanced protection layer is formed by an epoxy molding compound.

20. The package as claimed in claim 15, further comprising a build-up structure formed on the dielectric layer and the circuit layer.

21-22. (canceled)
